(19) United States
(12) Patent Application Publication
(10) Pub. No.: US 2017/0352542 A1
(43) Pub. Date: Dec. 7, 2017

(54) NANOSCALE WIRES WITH TIP-LOCALIZED JUNCTIONS

(71) Applicant: President and Fellows of Harvard College, Cambridge, MA (US)

(72) Inventors: Charles M. Lieber, Lexington, MA (US); Ruixuan Gao, Cambridge, MA (US); Max Nathan Mankin, Cambridge, MA (US); Robert Day, Somerville, MA (US); Hong-Gyu Park, Seoul (KR); You-Shin No, Cambridge, MA (US)

(21) Appl. No.: 15/522,992

(22) PCT Filed: Oct. 29, 2015
(86) PCT No.: PCT/US2015/057939

§ 371 Date: Apr. 28, 2017

Related U.S. Application Data
(60) Provisional application No. 62/072,518, filed on Oct. 30, 2014.

(51) Int. Cl. H01L 21/02; C23C 16/455; C23C 16/56; C30B 25/20; C30B 29/06; C30B 29/66; C30B 33/10; C23C 16/40; B82Y 40/00; H01L 33/44; H01L 29/06; H01L 29/16; H01L 29/36; H01L 31/0216; H01L 31/028; H01L 31/0352; H01L 31/18; H01L 33/00; H01L 33/02; H01L 33/06; H01L 33/34

(52) U.S. Cl. CPC H01L 21/02653; H01L 21/02603; C23C 16/402; C23C 16/45525; C23C 16/56; C30B 25/20; C30B 29/06; C30B 29/66; C30B 33/10; H01L 21/02164; H01L 21/0228; H01L 21/02381; H01L 21/02433; H01L 21/02532; H01L 21/02584; B82Y 40/00; H01L 33/44; H01L 29/068; H01L 29/16; H01L 29/365; H01L 31/02161; H01L 31/028; H01L 31/035227; H01L 31/035272; H01L 31/1804; H01L 33/0054; H01L 33/025; H01L 33/06; H01L 33/34; H01L 29/0649

(57) ABSTRACT

The present invention generally relates to nanoscale wires and, in particular, to nanoscale wires with heterojunctions, such as tip-localized homo- or heterojunctions. In one aspect, the nanoscale wire may include a core, an inner shell surrounding the core, and an outer shell surrounding the inner shell. The outer shell may also contact the core, e.g., at an end portion of the nanoscale wire. In some cases, such nanoscale wires may be used as electrical devices. For example a p-n junction may be created where the inner shell is electrically insulating, and the core and the outer shell are p-doped and n-doped. Other aspects of the present invention generally relate to methods of making or using such nanoscale wires, devices, or kits including such nanoscale wires, or the like.

### RELATED APPLICATIONS

This application claims the benefit of U.S. Provisional Patent Application Ser. No. 62/072,518, filed Oct. 30, 2014, entitled “Nanoscale Wire Tip Modulation,” by Lieber, et al., incorporated herein by reference.

### FIELD

The present invention generally relates to nanoscale wires and, in particular, to nanoscale wires with heterojunctions, such as tip-localized homo- or heterojunctions.

### BACKGROUND

Structural diversity and synthetic tunability of nanowires has enabled diverse functionalities to be encoded in the one-dimensional nanostructure. Examples of nanowire structural motifs include axial and radial modulations. See, for example, U.S. Pat. No. 7,301,199, incorporated herein by reference. These basic motifs can be used as electrical or optical device elements. For example, an axial p-n junction nanowire can function as a nanoscale photon source. However, in such structures, the encoded functionalities often either extend through the whole nanowire, or require additional electrical contacts in proximity, which may limit their uses. Consequently, new nanoscale wire structures may be useful regarding the above issues and generating novel device functionalities.

### SUMMARY

The present invention generally relates to nanoscale wires and, in particular, to nanoscale wires with heterojunctions, such as tip-localized homo- or heterojunctions. The subject matter of the present invention involves, in some cases, interrelated products, alternative solutions to a particular problem, and/or a plurality of different uses of one or more systems and/or articles.

In one aspect, the present invention is directed to an article. In one set of embodiments, the article includes a nanowire comprising a core, an inner shell surrounding the core except at an end of the core, and an outer shell surrounding the inner shell and contacting the end of the core.

In another set of embodiments, the article comprises a nanowire comprising a core having an end portion, an inner shell surrounding the core except at the end portion, and an outer shell surrounding the inner shell and contacting the core at the end portion.

The article, in yet another set of embodiments, includes a nanowire comprising a core, an inner shell surrounding the core, and an outer shell surrounding the inner shell, wherein the core and the outer shell are in physical contact with each other.

The article, in still another set of embodiments, includes a nanowire comprising a core, an inner shell surround the core except at an end of the core, and one or more outer shells surrounding the inner shell and contacting the end of the core.

In another aspect, the present invention is generally directed to methods of making or using nanowires. For example, in one set of embodiments, the method includes providing a nanowire vertically oriented on a substrate; coating the nanowire with a first material; selectively removing a portion of the first material from an end of the nanowire; and coating the nanowire with a second material.

In another aspect, the present invention encompasses methods of making one or more of the embodiments described herein, for example, a heterojunction nanoscale wire such as is discussed herein. In still another aspect, the present invention encompasses methods of using one or more of the embodiments described herein, for example, a heterojunction nanoscale wire such as is discussed herein.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIGS. 1A-1C illustrate certain tip-localized junction nanowires according to one set of embodiments;

FIGS. 2A-2E illustrate electrical characterization of nanowires according to another set of embodiments;

FIGS. 3A-3G illustrate optical characterization of nanowires according to yet another set of embodiments;

FIGS. 4A-4D illustrate synthesis of nanowires in accordance with still another set of embodiments;

FIGS. 5A-5B illustrate nanowires in accordance with yet another set of embodiments;

FIG. 6 is a high resolution transmission electron microscope image of a p-n junction in another embodiment;

FIG. 7 illustrates a technique for fabricating a nanowire in another set of embodiments;

FIG. 8 illustrates a log(I)-V plot of a nanowire in yet another embodiment;

FIG. 9 illustrates a technique for fabricating a nanowire in still another set of embodiments;

FIGS. 10A-10B illustrate certain nanowires in accordance with another set of embodiments of the invention;

FIG. 11 illustrates large-scale synthesis of nanowires on a surface, in yet another set of embodiments;

FIGS. 12A-12B illustrate a p-Si/i-Si/p-Si tip junction according to still another embodiment of the invention; and

FIGS. 13A-13B illustrate a p-Si/CdS tip heterojunction in accordance with another embodiment of the invention.

### DETAILED DESCRIPTION

The present invention generally relates to nanoscale wires and, in particular, to nanoscale wires with heterojunctions, such as tip-localized homo- or heterojunctions. In one aspect, the nanoscale wire may include a core, an inner shell surrounding the core, and an outer shell surrounding the inner shell. The outer shell may also contact the core, e.g., at an end portion of the nanoscale wire. In some cases, such nanoscale wires may be used as electrical devices. For example a p-n junction may be created where the inner shell is electrically insulating, and the core and the outer shell are p-doped and n-doped. Other aspects of the present invention generally relate to methods of making or using such nanoscale wires, devices, or kits including such nanoscale wires, or the like.

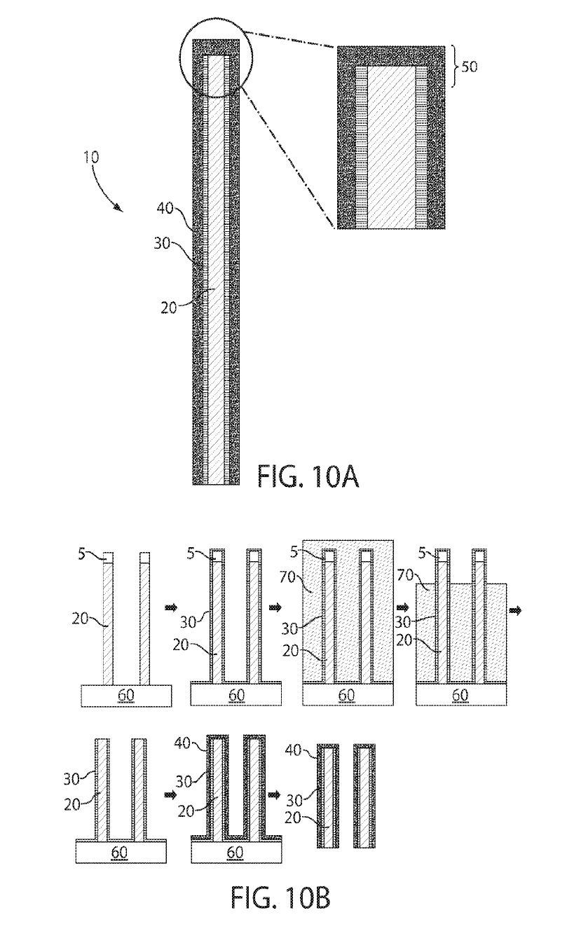

Various example embodiments of the invention are now described with respect to FIG. 10A. However, as will be discussed in more detail below, in other aspects, other configurations may be used as well. In this figure, nanowire 10 is shown, including a core 20, an inner shell 30, and an outer shell 40. In this example, nanowire 10 is substantially cylindrical, although other shapes are also possible in other embodiments.

Typically, the core and shells are fabricated from semiconductor materials such as silicon, germanium, or dielectric materials. Core 20 may be, for example, a silicon nanowire, and may be undoped, p-doped, n-doped, etc. Surrounding core 20 is inner shell 30. It should be noted, however, that at an end portion 50 of the nanowire, inner shell 30 ends and does not completely surround core 20, thus leaving an end portion of core 20 that is free of inner shell 30. In addition, surrounding inner shell 30 is outer shell 40. Outer shell 40 may come into contact with both inner shell 30 and with core 20, e.g., at the end portion of core 20 that is free of inner shell 30. However, it should be noted that core 20 and outer shell 40 only come into contact with each other at end portion 50; in other portions of nanowire 10, core 20 and outer shell 40 are not in contact with each other, but are separated by inner shell 30.

As noted, the core, inner shell, and outer shell may be formed of different materials. For instance, in one set of embodiments, the core and outer shell may be composed of semiconductive materials, separated by an inner shell composed of a dielectric material. Accordingly, the core and outer shell may not contact each other except for at the end portion of the core. In this way, the electrical connection between the core and the outer shell may be confined to a small region of the nanowire. Thus, for example, the core and the outer shell may be differently doped (or undoped) to create a junction of two semiconductor materials, such as a p-n junction. For instance, the core may be p-doped and the outer shell may be n-doped (or vice versa).

A variety of techniques may be used to fabricate such nanowires. One non-limiting example is as follows, although other materials and/or other techniques can also be used in other embodiments, e.g., as discussed herein. In FIG. 10B, a silicon nanowire core 20 may be grown from a gold nanoparticle 5 on a substrate 60, e.g., using any suitable technique, such as epitaxial vapor-liquid-solid (VLS) growth. Next, an inner shell (for example, a dielectric such as SiO₂) may be deposited around the nanowire core, e.g., using conformal growth techniques such as atomic layer deposition (ALD). It should be noted that in some cases, inner shell 30 may coat all of core 20, including the end portion.

The end portion of the structure may then be removed, for example, as follows. A protective layer 70 (for example, comprising a resist) may be deposited around the nanowires, e.g., completely covering the nanowires. The resist material may be, for example, SU-8 or methyl methacrylate (MMA). Next, the resist may be etched partially to expose the ends of the nanowires above the surface of the resist, followed by ultrasonication or other techniques to remove the portions of the nanowires that are exposed above the surface of the resist. The resist may then be removed, e.g., by using acetone and/or plasma. Afterwards, an outer shell 40 may be added, e.g., using VS (vapor-solid) growth, ALD, or other suitable techniques. Optionally, the nanowires may then be removed from the substrate.

It should be understood that the above descriptions are by way of example only, and other nanowires and techniques for making nanowires are also possible in other aspects of the invention. For example, in one aspect, the present invention is generally directed to various nanoscale wires having a core and one, two, three, four, or more shell regions, e.g., in a nested configuration. For example, a shell may surround a core except for an end portion of a core, or an outer shell may surround an inner shell that surrounds the core.

In some embodiments, the core may comprise or consist essentially of a semiconductor, e.g., silicon or germanium. Examples of semiconductors and dielectrics, and properties of such materials, are discussed in additional detail below. The core may be doped (e.g., p-doped or n-doped), or undoped, e.g., as discussed herein. Techniques for producing nanoscale wires are known to those of ordinary skill in the art, and include, for instance, vapor-liquid-solid (VLS) techniques, solution-phase synthesis techniques or solution processing techniques, template fabrication techniques, chemical vapor deposition (CVD), or the like. See, for instance, U.S. Pat. No. 7,211,464, issued May 1, 2007, entitled “Doped Elongated Semiconductors, Growing Such Semiconductors, Devices Including Such Semiconductors and Fabricating Such Devices,” by Lieber, et al., incorporated herein by reference in its entirety.

In addition, in some cases, the core itself may comprise a heterojunction, e.g., an axial heterojunction or a longitudinal heterojunction. See, for example, FIG. 12A, as an example of a core comprising a heterojunction. Various techniques for forming a heterojunction in a nanowire may be found in, for example, U.S. Pat. No. 7,301,199, issued Nov. 27, 2007, entitled “Nanoscale Wires and Related Devices,” by Lieber, et al., incorporated herein by reference in its entirety.

The core region may have any shape, e.g., the core region may be relatively straight, or the core region may be bent or kinked. See, e.g., Int. Pat. Apl. Ser. No. PCT/US10/50199, filed Sep. 24, 2010, entitled “Bent Nanowires and Related Probing of Species,” published as Int. Pat. Apl. Pub. No. WO 2011/038228 on Mar. 31, 2011, incorporated herein by reference in its entirety. In addition, in certain embodiments, the core may have a shape such that an imaginary straight line connecting two points of the nanoscale wire farthest away from each other along the nanoscale wire may not exit the nanoscale wire.

In some embodiments, the core is generally cylindrical. In other embodiments, however, other shapes are possible; for example, the core may be a faceted nanoscale wire, i.e., the nanoscale wire may have a polygonal cross-section. The cross-section of the core may be of any arbitrary shape, including, but not limited to, circular, square, rectangular, annular, polygonal, or elliptical, and may be a regular or an irregular shape.

In some cases, the core may be a nanoscale wire or other nanoscale object, that at any point along its length, has at least one cross-sectional dimension and, in some embodiments, two orthogonal cross-sectional dimensions (e.g., a diameter) of less than about 1 micrometer, less than about 500 nm, less than about 200 nm, less than about 150 nm, less than about 100 nm, less than about 70, less than about 50 nm, less than about 20 nm, less than about 10 nm, less than about 5 nm, than about 2 nm, or less than about 1 nm. In some cases, the core may have at least one-cross sectional dimension greater than about 1 nm, greater than about 2 nm, greater than about 5 nm, greater than about 10 nm, greater than about 20 nm, greater than about 50 nm, greater than about 70 nm, greater than about 100 nm, greater than about 150 nm, greater than about 200 nm, greater than about 500 nm, etc. Combinations of these are also possible, e.g., the core may have a cross-sectional dimension of between about 10 nm and about 200 nm.

In some cases, the core has one dimension that is substantially longer than the other orthogonal dimensions of the core. For example, the core may have a longest dimension that is at least about 1 micrometer, at least about 3 micrometers, at least about 5 micrometers, or at least about 10 micrometers or about 20 micrometers in length, or the core may have an aspect ratio (longest dimension to shortest orthogonal dimension) of greater than about 2:1, greater than about 3:1, greater than about 4:1, greater than about 5:1, greater than about 10:1, greater than about 25:1, greater than about 50:1, greater than about 75:1, greater than about 100:1, greater than about 150:1, greater than about 250:1, greater than about 500:1, greater than about 750:1, or greater than about 1000:1 or more in some cases.

In some embodiments, the core may be substantially uniform, or have a variation in average diameter of less than about 30%, less than about 25%, less than about 20%, less than about 15%, less than about 10%, or less than about 5%. For example, the core may be grown from substantially uniform nanoclusters or particles, e.g., colloid particles.

Examples of such techniques may be found in, e.g., U.S. Pat. No. 7,301,199, issued Nov. 27, 2007, entitled “Nanoscale Wires and Related Devices,” by Lieber, et al., incorporated herein by reference in its entirety.

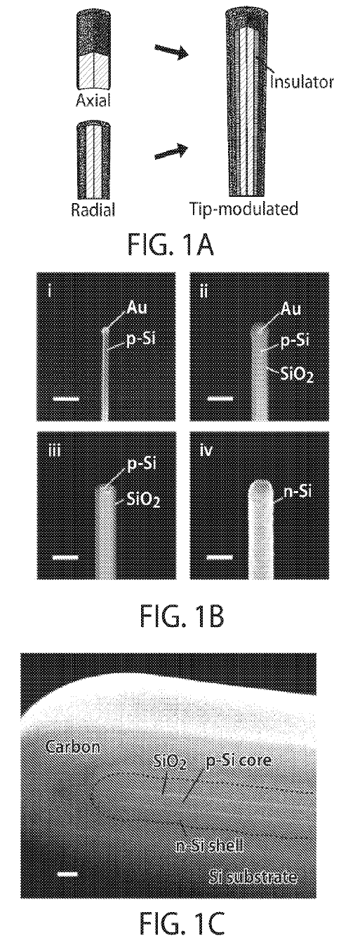

Surrounding the core may be a first or inner shell, and a second or outer shell surrounding the inner shell. See, for instance, FIG. 1A. In some cases, two, three, four, or more shells are possible. Each shell may independently comprise a semiconductor (e.g., silicon or germanium), a dielectric, or other materials. For instance, the inner shell may comprise a dielectric material while the outer shell may comprise a semiconductor.

In one set of embodiments, a shell may be an insulator. For instance, the shell may comprise materials having a resistivity of at least 10¹² Ohm-m, at least 10¹⁵ Ohm-m, or at least 10¹⁸ Ohm-m. Different materials may be chosen for the core and the shells, and/or one or more of these may be formed from the same materials. For instance, the core may be formed from a first material (e.g., a semiconductor), an inner shell may be formed from a second material (e.g., a dielectric), and an outer shell may be formed from the first material or from a third material different from the first and second materials. As other non-limiting examples, a nanowire may have three shells, which may be formed from different materials, or the first and third shells may be formed from the same material, etc.

Examples of suitable dielectric materials include, but are not limited to, a semiconductor oxide (e.g., silicon dioxide), a metal (e.g., Ni, Pt, Au, etc.), a polymer (e.g., polyaniline, polypyrrole, etc.), or the like. Other non-limiting examples of dielectric materials include a nitride, such as Si₃N₄, or an oxide, such as a semiconductor oxide or a metal oxide. In one embodiment, the semiconductor oxide is SiO₂. In another embodiment, the semiconductor oxide is GeO₂. In still other embodiments, the oxide may be SeO₂, SnO₂, GaO₂, TiO₂, Al₂O₃, HfO₂, NiO₂, NiO, BaTiO₃, SrTiO₃, Fe₃O₄, Fe₂O₃, MgO, Cr₂O₃, ZnO, MgO, VO₂, V₂O₅, MnO, Co₂O₃, Co₃O₄, CuO, Cu₂O, ZrO₂, BaO, WO₂, CeO₂, or the like. Other examples include NdFeB, or any other suitable material that is dielectric. Combinations of any of these are also possible in some cases, e.g., the semiconductor oxide may comprise SiO₂ and GeO₂, SiO₂ and SeO₂, etc. In some cases, at least about 80%, at least about 85%, at least about 90%, at least about 95%, or 100% of a shell (by mass) is a semiconductor oxide.

The shells may each independently have any suitable thickness, and the thickness may be constant or may vary. The thickness of the various shells may independently be the same or different. In one set of embodiments, the shell may have an average thickness of less than about 300 nm, less than about 200 nm, less than about 150 nm, less than about 100 nm, less than about 70, less than about 50 nm, less than about 30 nm, less than about 20 nm, less than about 10 nm, less than about 5 nm, less than about 3 nm, less than about 2 nm, or less than about 1 nm. In some cases, the shell may have an average thickness of at least about 1 nm, at least about 2 nm, at least about 3 nm, at least about 5 nm, at least about 10 nm, at least about 20 nm, at least about 30 nm, at least about 50 nm, at least about 100 nm, etc. Combinations of any of these are also possible. As a non-limiting example, a shell (which may be, for instance, an inner shell, an outer shell, or one of the middle shells in certain cases) may have an average thickness of between about 10 nm and about 100 nm. In addition, in some embodiments, a shell (e.g., an inner shell or an outer shell) may have a thickness that is less than about 25%, less than about 20%, less than about 15%, less than about 10%, or less than about 5% of the average diameter of the nanowire.

A shell typically surrounds all, or substantially all, of an inner shell, or the core if it is the innermost shell. For instance, with respect to the innermost shell, if the core is substantially cylindrical, the shell may surround or come into contact with all of the core, e.g., except for one or both ends of the core. In some cases, for instance, the inner shell may come into contact at least about 80%, at least about 85%, at least about 90%, or at least about 95% of the surface of the core. In some cases, no more than about 15%, no more than about 10%, or no more than about 5% of the surface of the core may be free of the inner shell.

Similarly, an outer shell may surround all, or substantially all, of an inner shell. For example, the outer shell may come into contact with at least about 80%, at least about 85%, at least about 90%, or at least about 95% of the outer surface of the inner shell. In addition, in some embodiments, an outer shell may come into contact with the core, e.g., in one or more portions that do not come into contact with an inner shell. As a non-limiting example, in FIG. 10A, core 20 is substantially surrounded by inner shell 30, except for one end, which come into contact instead with outer shell 40.

In some cases, the junction between the core and a shell (e.g., between the core and an outer shell), or between two shells within the nanowire, may be a heterojunction, e.g., of two regions with dissimilar materials or elements, and/or the same materials or elements but at different ratios or concentrations. There may be a single junction, or in some cases, more than one junction or connection between the core and the shell, or between the two shells. In one embodiment, the junction may be a p-n junction, e.g., where one of the materials of the junction is p-doped and the other material is n-doped. The junctions may also be, for example, a p-p junction, an n/n junction, a p-i junction (where i refers to an intrinsic semiconductor), an n-i junction, an i-i junction, or the like. The junction may also be a Schottky junction in some embodiments. The junction may also be, for example, a semiconductor/semiconductor junction, a semiconductor/metal junction, a semiconductor/insulator junction, a metal/metal junction, a metal/insulator junction, an insulator/insulator junction, or the like. The junction may be a junction of two materials, a doped semiconductor to a doped or an undoped semiconductor, or a junction between regions having different dopant concentrations. The junction may also be a defected region to a perfect single crystal, an amorphous region to a crystal, a crystal to another crystal, an amorphous region to another amorphous region, a defected region to another defected region, an amorphous region to a defected region, or the like.

Thus, for example, in one set of embodiments, a nanoscale wire may comprise a core having a first material and an outer shell having a second material, such that the core and the outer shell form a desired heterojunction, e.g., a p-n heterojunction. The core and the outer shell may be separated by an inner shell, e.g., covering the core except at an end, or one or more portions of the core. In some cases, the inner shell may be an electrically insulating or a dielectric material that separates the core and the outer shell such that the core and the outer shell only come into contact in a particular region, e.g., an end region of the core. In contrast, in many prior art nanowires, there is usually no direct contact between the core and an outer shell, i.e., the inner shell is positioned to prevent all direct physical contact occurring between the core and the outer shell.

As previously discussed, in some aspects, the core and/or or one or more of the shells (e.g., an outer shell) of the nanoscale wire may be a semiconductor. Typically, a semiconductor is an element having semiconductive or semi-metallic properties (i.e., between metallic and non-metallic properties). An example of a semiconductor is silicon. Other non-limiting examples include elemental semiconductors, such as gallium, germanium, diamond (carbon), tin, selenium, tellurium, boron, or phosphorous. In other embodiments, more than one element may be present in the nanoscale wire as the semiconductor, for example, gallium arsenide, gallium nitride, indium phosphide, cadmium selenide, etc. Still other examples include a Group II-VI material (which includes at least one member from Group II of the Periodic Table and at least one member from Group VI, for example, ZnS, ZnSe, ZnSSe, ZnCdS, CdS, or CdSe), or a Group III-V material (which includes at least one member from Group III and at least one member from Group V, for example GaAs, GaP, GaAsP, InAs, InP, AlGaAs, or InAsP).

In some cases, the semiconductor will have the ability to pass electrical charge, for example, by being electrically conductive. For example, the semiconductor may have a relatively low resistivity, e.g., less than about 10⁻³ Ohm m (Ωm), less than about 10⁻⁴ Ohm m, less than about 10⁻⁶ Ohm m, or less than about 10⁻⁷ Ohm m. The semiconductor may, in some embodiments, have a conductance of at least about 1 microsiemens, at least about 3 microsiemens, at least about 10 microsiemens, at least about 30 microsiemens, or at least about 100 microsiemens.

In certain embodiments, the semiconductor may be undoped or doped (e.g., p-type or n-type). For example, in one set of embodiments, a portion of the nanowire may be a p-type semiconductor or an n-type semiconductor. In some embodiments, a dopant or a semiconductor may include mixtures of Group IV elements, for example, a mixture of silicon and carbon, or a mixture of silicon and germanium. In other embodiments, the dopant or the semiconductor may include a mixture of a Group III and a Group V element, for example, BN, BP, BAs, AN, AlP, AlAs, AlSb, GaN, GaP, GaAs, GaSb, InN, InP, InAs, or InSb. Mixtures of these may also be used, for example, a mixture of BN/BP/BAs, or BN/AlP. In other embodiments, the dopants may include alloys of Group III and Group V elements. For example, the alloys may include a mixture of AlGaN, GaPAs, InPAs, GaInN, AlGaInN, GaInAsP, or the like. In other embodiments, the dopants may also include a mixture of Group II and Group VI semiconductors. For example, the semiconductor may include ZnO, ZnS, ZnSe, ZnTe, CdS, CdSe, CdTe, HgS, HgSe, HgTe, BeS, BeSe, BeTe, MgS, MgSe, or the like. Alloys or mixtures of these dopants are also be possible, for example, (ZnCd)Se, or Zn(SSe), or the like. Additionally, alloys of different groups of semiconductors may also be possible, for example, a combination of a Group II-Group VI and a Group III-Group V semiconductor, for example, (GaAs)ₓ(ZnS)₁₋ₓ. Other examples of dopants may include combinations of Group IV and Group VI elements, such as GeS, GeSe, GeTe, SnS, SnSe, SnTe, PbO, PbS, PbSe, or PbTe. Other semiconductor mixtures may include a combination of a Group I and a Group VII, such as CuF, CuCl, CuBr, CuI, AgF, AgCl, AgBr, AgI, or the like. Other dopant compounds may include different mixtures of these elements, such as BeSiN₂, CaCN₂, ZnGeP₂, CdSnAs₂, ZnSnSb₂, CuGeP₃, CuSi₂P₃, Si₃N₄, Ge₃N₄, Al₂O₃, (Al, Ga, In)₂(S, Se, Te)₃, Al₂CO₃ (Cu, Ag)(Al, Ga, In, Tl, Fe)(S, Se, Te)₂ and the like.

The doping of the semiconductor to produce a p-type or n-type semiconductor may be achieved a variety of doping mechanisms. For example, in one set of embodiments, a doped nanoscale wire may be prepared by incorporating a dopant during catalyzed growth of the nanoscale wire (or portion thereof, e.g., a doped Si shell), e.g., during chemical vapor deposition (CVD). Thus, as non-limiting examples, a p-type nanoscale wire may be prepared by incorporating boron (or other suitable p-type dopants as described herein) during growth of the nanoscale wire, or an n-type nanoscale wire may be prepared by incorporating phosphorous (or other suitable n-type dopants as described herein) during growth of the nanoscale wire. As a specific non-limiting example, a p-type silicon nanowire may be synthesized by flowing both SiH₄ (silane) and B₂H₆ (diborane) gases in a CVD system.

Other doping techniques may also be used in other embodiments of the invention, for example, bulk-doping, ion implantation, etc. Many such doping techniques that can be used will be familiar to those of ordinary skill in the art, including both bulk doping and surface doping techniques. A bulk-doped article (e.g. an article, or a section or region of an article) is an article for which a dopant is incorporated substantially throughout the crystalline lattice of the article, as opposed to an article in which a dopant is only incorporated in particular regions of the crystal lattice at the atomic scale, for example, only on the surface or exterior. For example, some articles are typically doped after the base material is grown, and thus the dopant only extends a finite distance from the surface or exterior into the interior of the crystalline lattice. It should be understood that “bulk-doped” does not define or reflect a concentration or amount of doping in a semiconductor, nor does it necessarily indicate that the doping is uniform. “Heavily doped” and “lightly doped” are terms the meanings of which are clearly understood by those of ordinary skill in the art. In some cases, one or more regions may comprise a single monolayer of atoms (“delta-doping”). In certain cases, the region may be less than a single monolayer thick (for example, if some of the atoms within the monolayer are absent). As a specific example, the regions may be arranged in a layered structure within the nanoscale wire, and one or more of the regions may be delta-doped or partially delta-doped.

In another aspect, the present invention is generally to systems and methods of making nanowires or other nanoscale wires such as those discussed herein. In some cases, the nanoscale wires may be prepared by fabricating a nanowire core, depositing or coating a material on the surface of the nanowire core, removing a portion of the coating and core (e.g., an end portion), and depositing a second material thereon. In addition, in some cases, the resulting nanoscale wire may be deposited on a surface and used in an electrical device, e.g., by defining one or more contacts on the nanoscale wire, which may be in electrical communication with any portion of the nanoscale wire.

Any suitable technique may be used to form the nanowire core, including vapor-liquid-solid (VLS) techniques, solution-phase synthesis techniques or solution processing techniques, template fabrication techniques, chemical vapor deposition (CVD), or the like. The core may also be undoped or doped, e.g., p-doped or n-doped. In some cases, the nanowire core may be formed on a surface using surface techniques. For example, the nanowire core may be grown by depositing particles (e.g., gold nanoparticles) on a suitable surface (e.g., a silicon or other semiconductor surface), and using CVD vapor-liquid-solid growth processes to epitaxially grow the nanowires up from the surface using the particles (e.g., “bottom-up” synthesis). In one set of embodiments, the nanowires are grown from a substrate, e.g., substantially vertically. In another set of embodiments, the nanowires may be formed through etching of material to form the nanowires (e.g., “top-down” synthesis).

The core may be formed out of a single material (e.g., silicon, germanium, or another suitable semiconductor material), or the core may comprise more than one material. For example, the core may comprise an axial or a longitudinal heterojunction of two or more materials, such as is taught in U.S. Pat. No. 7,301,199, incorporated herein by reference in its entirety. The core may also be branched and/or kinked in some embodiments, e.g., as is taught in U.S. Pat. No. 8,058,640 or U.S. Pat. Apl. Pub. No. 2012/0267604, each herein by reference in its entirety.

A shell may be deposited or otherwise formed around the nanowire core, for example using techniques for coating nanowires, such as atomic layer deposition (ALD), chemical vapor deposition (CVD), physical vapor deposition (PVD), spin-on deposition, screen printing, electrochemical deposition, or the like. Materials that may be used in the shell can be found herein. The thickness of the shell can be controlled, for example, by controlling the amount of deposition of material onto the nanowire. In addition, in some cases, more than one shell may be coated onto a nanowire core, e.g., sequentially.

In some cases, an end portion of the nanowire may be removed after coating with one or more shells. Any suitable technique may be used for removing an end portion of the nanowire. For example, in some cases, the nanowires may be attached to a surface and mechanical or chemical methods may be used to remove the end portions. In some cases, a resist may be used to facilitate removal of end portions of the nanowires, although it should be noted that this is not a requirement, and other techniques for removing end portions of the nanowires may also be used.

As a non-limiting example, in one set of embodiments, nanowires grown vertically on a surface may be coated in resist. Examples of suitable resist include, but are not limited to, photoresist such as SU-8, poly(methyl methacrylate) (PMMA), poly(methyl glutarimide) (PMGI), phenol formaldehyde resin (DNQ/Novolac), or the like. The upper portions of the resist may then be partially removed, e.g., upon exposure to oxygen plasma, electron beams, etchant (e.g., HF or BHF), ultrasonication, or other suitable techniques. The amount of resist that is removed (e.g., by controlling exposure times) can be used to control the length of the end portions that are removed. In some cases, the technique for removing the resist may also remove the end portions of the nanowires, although in certain cases, other techniques may be used to remove the end portions after removal of the resist. For instance, in some cases, the end portions of the nanowires may protrude from the surface of the resist after the resist has been partially removed, e.g., as is shown in FIG. 10B. The end portions may subsequently be removed using, for example, etching, ultrasonication, mechanical stimulation, or other suitable techniques. During such techniques, the remaining resist may protect other portions of the nanowires such that only the end portions are generally removed. The remaining resist may then be removed, for example, using etching techniques similar to the ones discussed above.

Upon removal of the end portions of the nanowires, one or more shells may then be coated on the nanowire, e.g., using deposition techniques such as those described above. Examples of materials that may be used in the outer shell can be found herein, and the outer shell may be the same or different than the materials in the inner shell. The same or different deposition techniques also can be used. In addition, in some cases, more than one shell may be added.

Afterwards, the nanowires may optionally be removed from the substrate using any suitable technique, such as shear transfer, contact-printing, or nanocombing, e.g., as discussed in Yao, et al., “A Nanoscale Combing Technique for the Large-Scale Assembly of Highly Aligned Nanowires,” Nature Nanotech., 8:329-335, 2013. See also Int. Pat. Apl. Ser. No. PCT/US2007/008540, filed Apr. 6, 2007, entitled “Nanoscale Wire Methods and Devices,” published as WO 2007/145701 Dec. 21, 2007, incorporated herein by reference in its entirety. In some cases, the nanowires may also be generally aligned. The nanowires may also be deposited onto a substrate, and contacts defined with one or more portions of the nanowires (e.g., a core, inner shell, outer shell, etc.) to form a component for an electrical circuit. Techniques for forming contacts on a nanowire, and etching portions of the nanowire to define contacts, are known to those of ordinary skill in the art. See, e.g., Int. Pat. Apl. Pub. No. WO 2005/093831, incorporated herein by reference. A contact may contact any suitable portion of the nanowire, e.g., a core, inner shell, outer shell, or the like. Two, three, or more contacts may also be defined onto a nanowire in some embodiments, e.g., a first contact in electrical communication with the core and a second contact in electrical communication with an outer shell.

As mentioned, certain aspects of the invention are generally directed to nanowires or other nanoscale wires. The nanoscale wire may be formed of suitable materials, e.g., semiconductors, metals, etc., as well as any suitable combinations thereof, e.g., as discussed herein. In general, a “nanoscale wire” (also known herein as a “nanoscopic-scale wire” or “nanoscopic wire”) generally is a wire or other nanoscale object, that at any point along its length, has at least one cross-sectional dimension and, in some embodiments, two orthogonal cross-sectional dimensions (e.g., a diameter) of less than about 1 micrometer, less than about 500 nm, less than about 200 nm, less than about 150 nm, less than about 100 nm, less than about 70, less than about 50 nm, less than about 20 nm, less than about 10 nm, less than about 5 nm, than about 2 nm, or less than about 1 nm. In the case of a nanotube (which may be partially or completely hollow), the shell may have any suitable thickness, e.g., less than about 500 nm, less than about 200 nm, less than about 150 nm, less than about 100 nm, less than about 70, less than about 50 nm, less than about 20 nm, less than about 10 nm, less than about 5 nm, than about 2 nm, or less than about 1 nm.

In some embodiments, the nanoscale wire is generally cylindrical. In other embodiments, however, other shapes are possible; for example, the nanoscale wire can be faceted, i.e., the nanoscale wire may have a polygonal cross-section. The cross-section of a nanoscale wire may be of any arbitrary shape, including, but not limited to, circular, square, rectangular, annular, polygonal, or elliptical, and may be a regular or an irregular shape. The nanoscale wire may also be solid (e.g., as in a nanowire) or hollow (e.g., as in a nanotube).

In some cases, the final nanoscale wire has one dimension that is substantially longer than the other dimensions of the nanoscale wire. For example, the nanoscale may have a longest dimension that is at least about 1 micrometer, at least about 3 micrometers, at least about 5 micrometers, or at least about 10 micrometers or about 20 micrometers in length, or the nanoscale wire may have an aspect ratio (longest dimension to shortest orthogonal dimension) of greater than about 2:1, greater than about 3:1, greater than about 4:1, greater than about 5:1, greater than about 10:1, greater than about 25:1, greater than about 50:1, greater than about 75:1, greater than about 100:1, greater than about 150:1, greater than about 250:1, greater than about 500:1, greater than about 750:1, or greater than about 1000:1 or more in some cases.

In some embodiments, a nanoscale wire may be substantially uniform, or have a variation in average diameter of less than about 30%, less than about 25%, less than about 20%, less than about 15%, less than about 10%, or less than about 5%. For example, the nanoscale wires may be grown from substantially uniform nanoclusters or particles, e.g., colloid particles. See, e.g., U.S. Pat. No. 7,301,199, issued Nov. 27, 2007, entitled “Nanoscale Wires and Related Devices,” by Lieber, et al., incorporated herein by reference in its entirety.

In some (but not all) embodiments, the nanoscale wires used herein are individual or free-standing nanoscale wires. For example, an “individual” or a “free-standing” nanoscale wire may, at some point in its life, not be attached to another article, for example, with another nanoscale wire, or the free-standing nanoscale wire may be in solution. This is in contrast to nanoscale features etched onto the surface of a substrate, e.g., a silicon wafer, in which the nanoscale features are never removed from the surface of the substrate as a free-standing article. This is also in contrast to conductive portions of articles which differ from surrounding material only by having been altered chemically or physically, in situ, i.e., where a portion of a uniform article is made different from its surroundings by selective doping, etching, etc. An “individual” or a “free-standing” nanoscale wire is one that can be (but need not be) removed from the location where it is made, as an individual article, and transported to a different location and combined with different components to make a functional device such as those described herein and those that would be contemplated by those of ordinary skill in the art upon reading this disclosure.

In one set of embodiments, a core or a shell of the nanoscale wire is formed from a single crystal, for example, a single crystal nanoscale wire comprising a semiconductor. A single crystal item may be formed via covalent bonding, ionic bonding, or the like, and/or combinations thereof. While such a single crystal item may include defects in the crystal in some cases, the single crystal item is distinguished from an item that includes one or more crystals, not ionically or covalently bonded, but merely in close proximity to one another.

In certain aspects, nanoscale wires as discussed herein may be used, for example, as probes that can be inserted into soft materials, polymers, tissues, biological systems, other materials, etc. Thus, more generally, certain embodiments of the invention are directed to various systems comprising nanoscale wires for use in determining properties of a tissue or other system, and methods of use thereof. Any suitable property may be determined and/or recorded, e.g., electrical properties, chemical properties, mechanical properties, etc. Examples of probes and probe structures that nanoscale wires such as those discussed herein may be used with include, but are not limited to Int. Pat. Apl. Ser. No. PCT/US2013/055910, filed Aug. 19, 2013, entitled “Nanoscale Wire Probes,” published as WO 2014/031709 on Feb. 27, 2014; U.S. Pat. Apl. Ser. No. 61/911,294, filed Dec. 3, 2013, entitled “Nanoscale Wire Probes for the Brain and Other Applications”; or U.S. Pat. Apl. Ser. No. 61/975,601, filed Apr. 4, 2014, entitled “Systems and Methods for Injectable Devices,” each incorporated herein by reference in its entirety.

Thus, a nanoscale wire as discussed herein may be used, according to some embodiments, to determine a property of the environment in and/or around the nanoscale wire, e.g., a chemical property, an electrical property, a physical property, etc. Such determination may be qualitative and/or quantitative. For example, in one set of embodiments, the nanoscale wire may be responsive to an electrical property such as voltage. For instance, the nanoscale wire can exhibit a voltage sensitivity of at least about 5 microsiemens/V; by determining the conductivity of a nanoscale wire, the voltage surrounding the nanoscale wire may thus be determined. In other embodiments, the voltage sensitivity may be at least about 10 microsiemens/V, at least about 30 microsiemens/V, at least about 50 microsiemens/V, or at least about 100 microsiemens/V. Other examples of electrical properties that can be determined include resistance, resistivity, conductance, conductivity, impendence, or the like.

As another example, the nanoscale wire may be used to determine a chemical property of the environment in and/or around the nanoscale wire. For example, an electrical property of the nanoscale wire can be affected by a chemical environment surrounding the nanoscale wire, and the electrical property can be thereby determined to determine the chemical environment. As a specific non-limiting example, the nanoscale wires may be sensitive to pH or hydrogen ions. Further non-limiting examples of such nanoscale wires are discussed in U.S. Pat. No. 7,129,554, filed Oct. 31, 2006, entitled “Nanosensors,” by Lieber, et al., incorporated herein by reference in its entirety.

As a non-limiting example, the nanoscale wire may have the inherent ability to bind to an analyte indicative of a chemical property of the environment in and/or around the nanoscale wire (e.g., hydrogen ions for pH, or concentration for an analyte of interest), and/or the nanoscale wire may be partially or fully functionalized, i.e. comprising surface functional moieties, to which an analyte is able to bind, thereby causing a determinable property change to the nanoscale wire, e.g., a change to the resistivity or impedance of the nanoscale wire. The binding of the analyte can be specific or non-specific. Functional moieties may include simple groups, selected from the groups including, but not limited to, —OH, —CHO, —COOH, —SO₃H, —CN, —NH₂, —SH, —COSH, —COOR, halide; biomolecular entities including, but not limited to, amino acids, proteins, sugars, DNA, antibodies, antigens, and enzymes; grafted polymer chains with chain length less than the diameter of the nanowire core, selected from a group of polymers including, but not limited to, polyamide, polyester, polyimide, polyacrylic; a shell of material comprising, for example, metals, semiconductors, and insulators, which may be a metallic element, an oxide, an sulfide, a nitride, a selenide, a polymer and a polymer gel.

In some embodiments, a reaction entity may be bound to a surface of the nanoscale wire, and/or positioned in relation to the nanoscale wire such that the analyte can be determined by determining a change in a property of the nanoscale wire. Thus, as specific non-limiting examples, one or more reaction entities may be positioned inside and/or outside of a nanotube. The determination may be quantitative and/or qualitative, depending on the application. The term “reaction entity” refers to any entity that can interact with an analyte in such a manner to cause a detectable change in a property (such as an electrical property) of a nanoscale wire. The reaction entity may enhance the interaction between the nanowire and the analyte, or generate a new chemical species that has a higher affinity to the nanowire, or to enrich the analyte around the nanowire. The reaction entity can comprise a binding partner to which the analyte binds. The reaction entity, when a binding partner, can comprise a specific binding partner of the analyte. For example, the reaction entity may be a nucleic acid, an antibody, a sugar, a carbohydrate or a protein. Alternatively, the reaction entity may be a polymer, catalyst, or a quantum dot. A reaction entity that is a catalyst can catalyze a reaction involving the analyte, resulting in a product that causes a detectable change in the nanowire, e.g. via binding to an auxiliary binding partner of the product electrically coupled to the nanowire. Another exemplary reaction entity is a reactant that reacts with the analyte, producing a product that can cause a detectable change in the nanowire. The reaction entity can comprise a shell on the nanowire, e.g. a shell of a polymer that recognizes molecules in, e.g., a gaseous sample, causing a change in conductivity of the polymer which, in turn, causes a detectable change in the nanowire.

The term “binding partner” refers to a molecule that can undergo binding with a particular analyte, or “binding partner” thereof, and includes specific, semi-specific, and non-specific binding partners as known to those of ordinary skill in the art. The term “specifically binds,” when referring to a binding partner (e.g., protein, nucleic acid, antibody, etc.), refers to a reaction that is determinative of the presence and/or identity of one or other member of the binding pair in a mixture of heterogeneous molecules (e.g., proteins and other biologics). Thus, for example, in the case of a receptor/ligand binding pair the ligand would specifically and/or preferentially select its receptor from a complex mixture of molecules, or vice versa. An enzyme would specifically bind to its substrate, a nucleic acid would specifically bind to its complement, an antibody would specifically bind to its antigen. Other examples include, nucleic acids that specifically bind (hybridize) to their complement, antibodies specifically bind to their antigen, and the like. The binding may be by one or more of a variety of mechanisms including, but not limited to ionic interactions, and/or covalent interactions, and/or hydrophobic interactions, and/or van der Waals interactions, etc.

Another aspect of the present invention is generally directed to essentially any electronic device that can benefit from adjacent n-type and p-type semiconducting components, e.g., using nanoscale wires as discussed herein. Essentially any device can be made in accordance with this aspect of the invention that one of ordinary skill in the art would desirably make using n-type and p-type semiconductors in combination. Examples of such devices include, but are not limited to, field effect transistors (FETs), bipolar junction transistors (BJTs), tunnel diodes, complementary inverters, light emitting devices, light sensing devices such as photodetectors, potentiometers, gates, inverters, AND, NAND, OR, and NOR gates, latches, flip-flops, registers, switches, clock circuitry, static or dynamic memory devices and arrays, state machines, gate arrays, and any other dynamic or sequential logic or other digital devices including programmable circuits. Also included are analog devices and circuitry, including but not limited to, amplifiers, switches and other analog circuitry using active transistor devices, as well as mixed signal devices and signal processing circuitry. For example, in one set of embodiments, a nanowire may produce different amounts of current in response to different voltages. Such a nanowire may be useful, for example, as a potentiometer. In another set of embodiments, a nanowire may produce different amounts of current in response to different amounts of incident light. Such a nanowire can be useful, for example, as a photodetector.

Electronic devices incorporating semiconductor nanowires can be controlled, for example, by electrical, optical or magnetic signals. The control may involve switching between two or more discrete states or may involve continuous control of nanowire current, i.e., analog control.

Light-emission sources are provided in accordance with certain embodiments of the invention as well, in which electrons and holes combine, emitting light. One type of light-emission source of the invention includes at least one p-n junction, e.g., using nanoscale wires as discussed herein. For example, when forward biased (positive charge applied to the p-type portion and a negative charge applied to the n-type portion), electrons may flow toward the junction in the n-type portion and holes flow toward the junction in the p-type portion. At the junction, holes and electrons may combine, emitting light. In addition, in some embodiments, the reverse may occur, e.g., incident light may cause holes and electrons to form, which may be used to create current or charge flow. Thus, in some cases, a nanoscale wire discussed herein may be used as a photodetector, or used to produce power from light, e.g., solar power.

The following documents are incorporated herein by reference in their entireties: U.S. Pat. Nos. 7,129,554, 7,211,464, 7,256,466, 7,301,199, 7,385,267, 7,476,596, 7,595,260, 7,619,290, 7,666,708, 7,911,009, 7,915,151, 7,956,427, 8,153,470, and 8,399,339; U.S. Pat. Apl. Pub. Nos. 2012/0267604, 2014/0073063, and 2014/0074253; U.S. Pat. Apl. Ser. Nos. 61/911,294 and 61/975,601; Int. Pat. Apl. Ser. No. PCT/US2007/008540, filed Apr. 6, 2007, entitled “Nanoscale Wire Methods and Devices,” published as WO 2007/145701 Dec. 21, 2007; and Int. Pat. Apl. Ser. No. PCT/US2013/055910, filed Aug. 19, 2013, entitled “Nanoscale Wire Probes,” published as WO 2014/031709 on Feb. 27, 2014; Int. Pat. Apl. Ser. No. PCT/US14/32743, filed Apr. 2, 2014, entitled “Three-Dimensional Networks Comprising Nanoelectronics.” Also incorporated herein by reference in its entirety is U.S. Provisional Patent Application Ser. No. 62/072,518, filed Oct. 30, 2014, entitled “Nanoscale Wire Tip Modulation,” by Lieber, et al.

The following examples are intended to illustrate certain embodiments of the present invention, but do not exemplify the full scope of the invention.

### EXAMPLE 1

The ability to rationally design and modulate structures and material compositions of semiconductor nanowires has led to nanoscale elements with unique properties and applications. These examples illustrate a novel nanowire structural motif, termed tip-modulated nanowire, in which the modulation of materials and dopants can be localized within tens of nanometers (with <10⁻¹⁴ m² junction area) at one end of the nanowire. These examples present a rational bottom-up synthesis of p-n junction formed at the nanowire tip. Selective-area water-gate response studies and spatially-resolved scanning photocurrent measurements show that the p-n junction can serve as a localized potentiometric sensor and highly-sensitive p-n diode photodetector at the nanowire tip. These examples also demonstrate a top-down approach for wafer-scale synthesis and device fabrication of vertical chemical sensor arrays. The synthetic generality and tunability of the new nanowire structures allows diverse functional elements to be encoded at the end of one-dimensional nanostructures with unprecedented spatial precision.

These examples illustrate a new nanowire structural motif, which is optimally designed for localization of electrical and optical functionalities at one end of the nanowire. In one example design of the tip-modulated nanowires, instead of an axial or radial modulation, material compositions and dopant profiles are modulated at the nanowire tip (FIG. 1A). In this example, the nanowire core and shell, which are insulated from each other by a dielectric layer that extends along the rest of the nanowire, form a tip-localized nanoscale junction. Notably, this structure combines merits of both the axial and radial modulated nanowires: a localized junction, similar to that of an axial junction, and an extended core/shell structure allowing geometrical freedom to define electrical contacts, similar to that of a radial nanowire device, are realized in the same nanowire structure. Further, by selecting different materials for the core, shell and the insulation layer, different device functionalities can be encoded at the nanowire tip. This example focuses on rational synthesis and device characterizations of tip-modulated nanowires with a Si p-n junction.

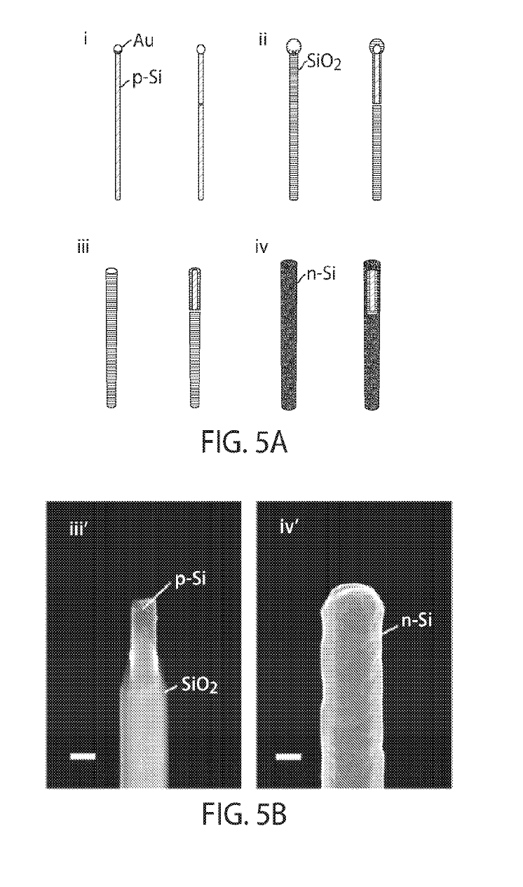

A two-step chemical vapor deposition (CVD) process of vapor-liquid-solid (VLS) core growth and vapor-solid (VS) shell growth was used to rationally synthesize nanowires with a tip Si p-n junction (see FIG. 5A). First, p-type Si nanowire cores were epitaxially grown on a Si <111> substrate with gold nanoparticle catalyzed VLS growth (FIG. 1B; i) and the as-synthesized nanowires were conformally coated with SiO₂ via atomic layer deposition (ALD) (FIG. 1B; ii). The growth substrate was then spin-coated with a protective resist layer, which was thinned in oxygen-plasma to expose the nanowire tip. After ultrasonication to mechanically remove the nanowire tip protruding from the resist, the protective resist layer was removed by dissolution in acetone and subsequent oxygen-plasma cleaning (FIG. 1B; iii). Immediately before the transfer of the growth substrate to the CVD chamber, the native oxide on the truncated tip was etched in buffered hydrofluoric acid (BHF) in order to form a clean tip junction. Finally, a conformal n-type Si shell was deposited in CVD with uncatalyzed VS growth (FIG. 1B; iv). It should be noted that dopant concentrations and physical dimensions of the core and shell can be finely controlled by tuning the synthetic conditions. In addition, the tip junction area and morphology can be tuned by, for example, introducing a BHF etching step after the tip-ultrasonication to partially remove the SiO₂ layer surrounding the nanowire sidewalls near the tip (FIG. 5B).

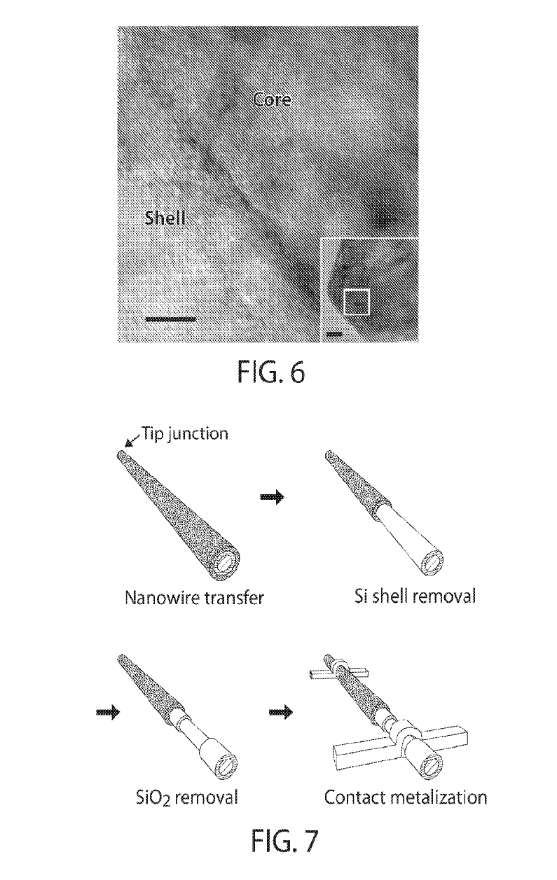

The as-synthesized nanowires with the tip Si p-n junction were shear-transferred to a Si substrate and cross-sectioned along the nanowire axis with a focused ion beam for material characterizations. SEM imaging of the cross-section shows that the nanowire core and shell were connected at the tip and that the SiO₂ insulation layer extended along the rest of the nanowire except for the tip junction (FIG. 1C). There was no visible interface or contrast difference between the core and shell at the nanowire tip, suggesting a clean and continuous junction. In addition, high resolution transmission electron microscopy (HRTEM) imaging of the junction interface showed that the lattice fringes were continuous from the core to the shell (FIG. 6). The SEM and TEM structural characterizations suggested that the structure of the synthesized tip-modulated follows this design.

FIG. 1 shows tip-modulated nanowire synthesis and material characterization. FIG. 1A illustrates schematics showing the axially, radially modulated (left) and tip-modulated (right) nanowire structures. FIG. 1B shows synthesis of a tip-modulated nanowire with a Si p-n junction. SEM images (45 degree tilt) of the same nanowire were taken for each synthetic step: (i) gold-nanoparticle-catalyzed vapor-liquid-solid (VLS) epitaxial nanowire growth of p-type core on Si <111> substrate; (ii) conformal ALD deposition of SiO₂ insulation layer; (iii) removal of the nanowire tip containing the gold nanoparticle via ultrasonication; (iv) conformal vapor-solid (VS) growth of n-type shell to form the tip junction. Scale bars, 200 nm. FIG. 1C shows SEM characterizations of the tip junction. The nanowire was longitudinally cross-sectioned by a focused ion beam to show the inner structure after the protective carbon layer deposition. The contour of the nanowire is specified by the broken line. Scale bar, 100 nm.

FIG. 5 shows tip-modulated nanowire synthesis. FIG. 5A shows schematics showing bottom-up synthesis of tip-modulated nanowires with the tip Si p-n junction. Steps (i)-(iv) correspond to the same steps described in FIG. 1B. The right panel in each schematic illustrates the partially half-cut inner structure of the nanowires. FIG. 5B shows synthetic variation of steps (iii) and (iv) in FIG. 1B. The SiO₂ layer was etched back (for 300-400 nm) with BHF after the tip removal (iii′). The subsequent VS growth of the n-Si shell yielded the final tip-modulated nanowire structure with different junction morphology (iv′). Scale bars, 100 nm.

FIG. 6 is a high resolution transmission electron microscope (HRTEM) characterization of the tip Si p-n junction. Bright-field HRTEM image of the tip junction interface. Scale bar, 5 nm. Inset, low magnification bright-field TEM image of the nanowire tip area (box specifying the area of the HRTEM image). The shell thickness is 20-25 nm. Scale bar, 20 nm.

### EXAMPLE 2

To characterize the electrical properties of the tip p-n junction, tip-modulated nanowire devices were fabricated by defining separate contacts to the core and the shell (FIG. 7). First, a section of the n-Si nanowire shell was removed by potassium hydroxide (KOH) aqueous solution while the nanowire tip end was protected in SU-8 resist as the etch mask. After removing the SU-8 resist mask, core and shell contacts were patterned with e-beam lithography. The SiO₂ insulation layer was then removed in BHF to expose the core, and the contacts were immediately metalized with thermal evaporation. The chemical selectivity for the SiO₂ insulation layer in the etching steps was important to the success of the device fabrication. In the first KOH etching step, the etch rate of Si was much faster (>70 times) than that of SiO₂, so that the SiO₂ insulation layer serves as etch top for the nanowire core. On the other hand, in the BHF etching, the Si shell was preserved during the SiO₂ removal, as the etch rate of Si was negligible compared to that of SiO₂.

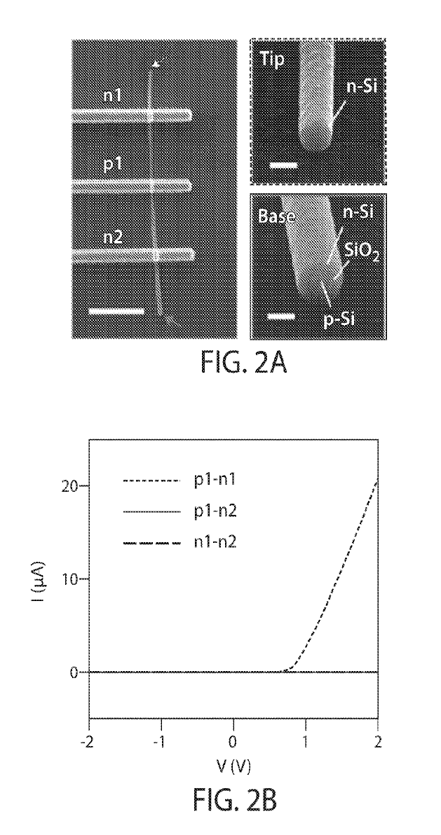

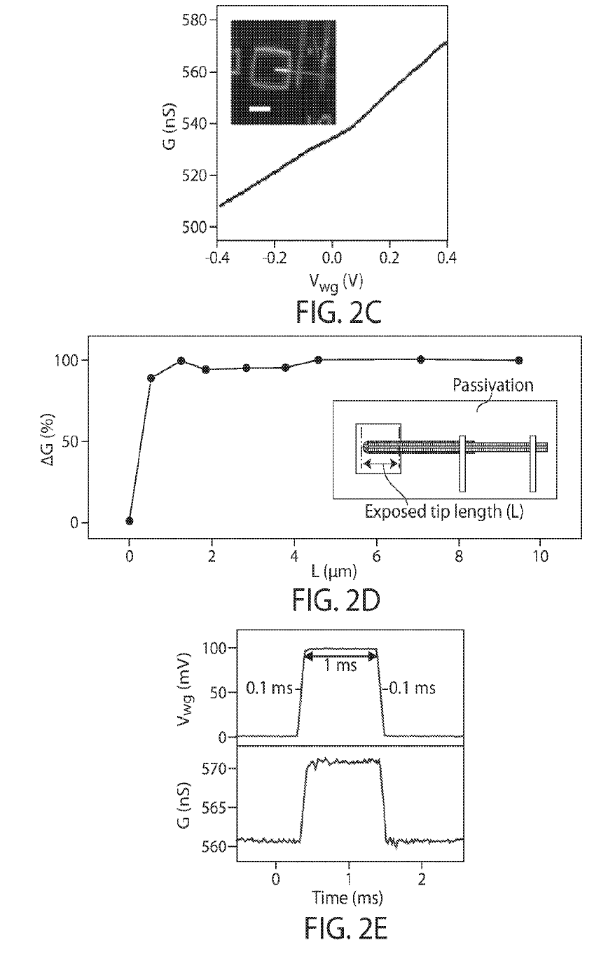

To closely study whether the p-n junction is localized at the nanowire tip, one common core contact and two shell contacts were defined—one close to the tip end and the other close to the broken base end, on the same tip-modulated nanowire (p1, n1 and n2 in FIG. 2A, respectively). The device I-V characteristics were first measured with different combinations of the core and shell contacts. The device with the common core and the tip end shell contacts (p1-n1) showed diode-like behavior while the control device with the common core and the broken end shell contacts (p1-n2) showed significantly smaller current for the same voltage sweep (FIG. 2B). This result demonstrated that a p-n junction existed on the tip side and no p-n junction was formed on the broken base side of the nanowire.

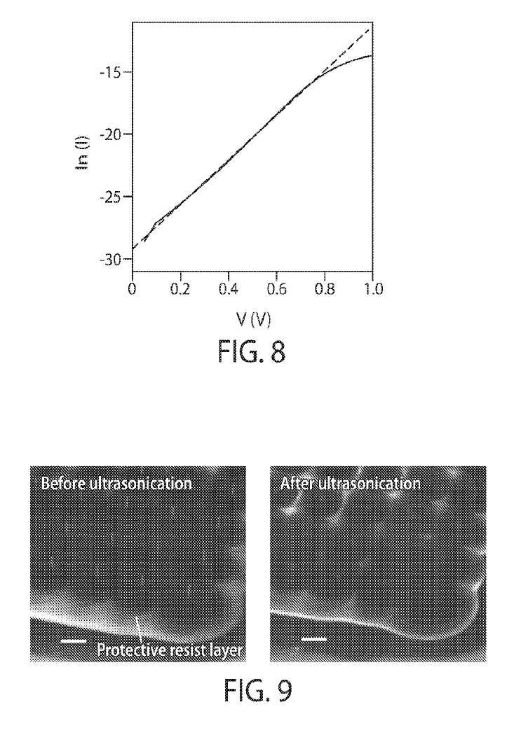

In addition, the current between the tip end and the broken end shell contacts (n1-n2) was measured with the same voltage sweep. Negligible leakage currents were observed, which further confirmed the success in the selective chemical etching to give our device structure. Furthermore, a linear fitting to a semi-log device I-V curve yielded an ideality factor of 2.16 and dark saturation current of 0.21 pA for a typical tip device (FIG. 8). These results suggested that the tip-modulated p-n junction functioned as a diode of better or comparable quality to the p-n junctions formed in other nanowire structures.

A selective-area water-gate experiment was also performed, in which part of the tip-modulated nanowire device was exposed to the electrolyte that served as the top-gate, while the rest of the device was passivated from the solution (FIG. 2C). At forward bias voltage, the device showed a transconductance of 79.7 nS/V with the quasi-static water-gate sweep. To quantitatively verify the localization of device sensitivity at the nanowire tip, the water-gate transconductance of a single device was repeatedly measured with different exposed nanowire tip lengths (FIG. 2D). The measurements showed that about 90% of the total transconductance (defined as the device transconductance with an exposed tip length of 9.5 micrometers) was localized at the 0.5 micrometer long tip and nearly 100% of the total transconductance was localized at the 1.2 micrometer long tip.

The device temporal resolution was further characterized by applying a fast water-gate voltage pulse (rise time down to 0.1 ms) (FIG. 2E). As a result, the conductance change followed well the applied pulse, suggesting the device colud record potential changes with time resolution of at least 0.1 ms (device bandwidth >3.5 kHz).

To summarize, the p-n junction of the tip-modulated nanowire device showed a clear diode-like electrical characteristics and could function as a potentiometer with the device sensitivity localized at the nanowire tip.

FIG. 2 shows electrical characterization of a tip-modulated nanowire device. FIG. 2A shows SEM characterizations of the tip-modulated nanowire device. Left: SEM image of a tip-modulated nanowire device with one core contact (p1) and two shell contacts (n1 and n2). Scale bar, 5 micrometers. Right top: high magnification SEM image of the tip end with the p-n junction (upper arrow). Scale bar, 200 nm. Right bottom: high magnification SEM image of the base end with no p-n junction (lower arrow). Scale bar, 200 nm.

FIG. 2B shows I-V curves were measured between the core-tip end shell (p1-n1), core-base end shell (p1-n2) and tip end shell-base end shell (n1-n2) contacts. FIG. 2C shows water-gate (top-gate) response of the tip-modulated nanowire device. Change of the device conductance (G) was recorded while the applied water-gate (V_{wg}) was swept from −0.4 to 0.4 V. The devices were forward biased at 1.5 V in all the water-gate measurements. Inset, dark-field optical microscope image of the device with the passivation window. The unpassivated tip length was ˜3.2 micrometers. Scale bar, 5 micrometers. FIG. 2D shows localized water-gate response from the nanowire tip. Water-gate transconductance (ΔG, delta G) of a tip-modulated nanowire device was measured repeatedly while the exposed nanowire tip length (L) was changed. The transconductance values were normalized with respect to that from the 9.5 micrometer nanowire tip (28.0 nS/V=100%). Inset: schematic showing the exposed nanowire tip length and passivation configuration. FIG. 2E shows a pulsed water-gate response of a tip-modulated nanowire device. The applied water-gate voltage was swept with 0.1 ms rise time (top) while the corresponding device conductance change was recorded (bottom). The unpassivated tip length was ˜3.2 micrometers.

FIG. 7 shows fabrication of the tip-modulated nanowire device. Schematics showing step-by-step fabrication of the tip-modulated nanowire device. FIG. 8 shows a dark state semi-log (log(I)-V) plot. The log(I)-V plot (solid line) is linearly extrapolated (broken black line) to estimate ideality factor (n=2.16) and dark saturation (I₀=0.21 pA) current of the device.

### EXAMPLE 3

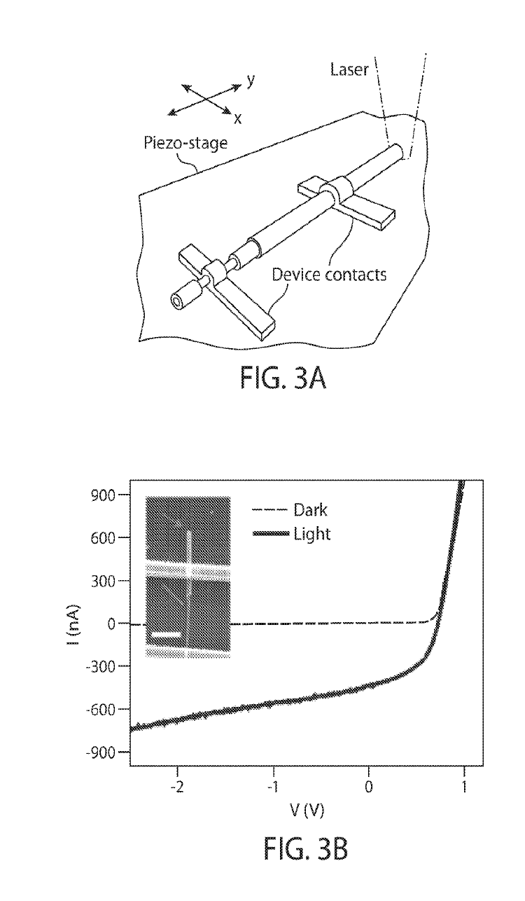

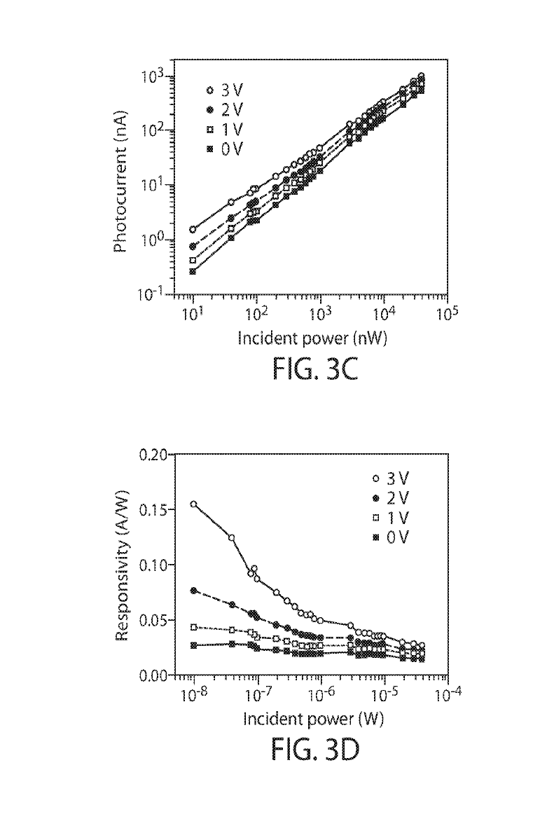

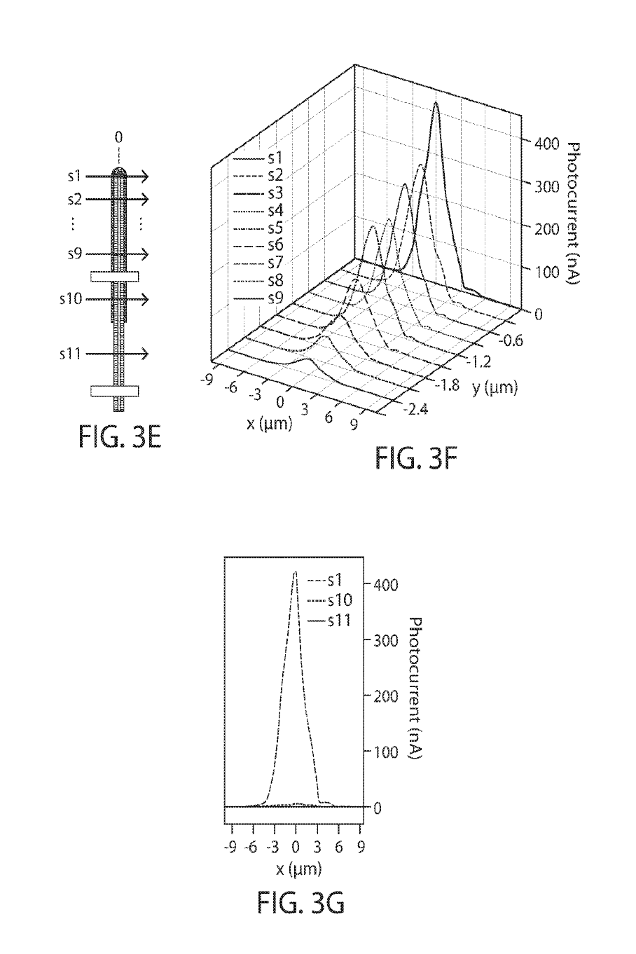

To show that the tip-modulated nanowire device can function as a localized and highly sensitive diode photodetector, this example shows carried out scanning photocurrent measurements. The photocurrent was measured with varying incident laser power, incident laser position and device bias voltage. The device mounted on a piezo-controlled movable stage was excited using the Ar-ion laser with a wavelength of 488 nm and a spot size of ˜1.6 micrometers (FIG. 3A). First, dark and light I-V curves of the device were measured when the laser beam was focused on the nanowire tip where the p-n junction was formed. As a result of light absorption and carrier generation and separation at the tip junction, the illuminated I-V curve showed an open-circuit voltage (V_{OC}) of 0.730 V and short-circuit current (I_{SC}) of 436 nA at an incident power of ˜29.3 microwatts (FIG. 3B). The photocurrent from the I-V curves as functions of different incident power and applied reverse bias voltages (FIG. 3C) was also obtained. The measured photocurrent revealed several important device features: (1) the photocurrent showed a linear dependence on the incident power; and (2) the photocurrent increased with the increasing reverse bias voltage. In addition, the responsivity of the tip-modulated nanowire device was estimated (FIG. 3D). As the incident power decreased, the device responsivity increased up to ˜0.15 A/W.

Next, spatially resolved photocurrent measurements were performed to investigate spatial dependence of the generated photocurrent. The incident laser spot was line-scanned across the tip-modulated nanowire device with different distances from the tip (step size 300 nm) along the nanowire axis (FIGS. 3E and 3F). In the scan going through the nanowire tip, the photocurrent reached maximum when the focused spot was on the tip (FIG. 3F). As the scan becomes more distant from the nanowire tip, a sharp decrease of the maximum photocurrent was observed. In particular, the maximum photocurrent measured 2.4 micrometers away from the tip was >11 times smaller than that measured for the scan going through the tip. Furthermore, the laser spot was scanned on the core/shell or core only regions between the two contacts, in which negligible photocurrents were observed (FIG. 3G). Taken together, the spatially resolved photocurrent measurement suggests that the photocurrent generation was strongly localized near the nanowire tip, where the localized p-n junction is formed.

FIG. 3 shows optical characterization of a tip-modulated nanowire device. FIG. 3A shows a schematic showing the tip-modulated nanowire device with the tip Si p-n junction mounted on a piezo-controlled movable stage with the laser focused on the device (wavelength 488 nm, spot size ˜1.6 micrometers). FIG. 3B shows dark and light I-V curves of the tip-modulated nanowire device with the laser spot focused on the nanowire tip. The incident laser power on the nanowire was ˜29.3 microwatts. Inset, SEM image of the device with the tip p-n junction specified by the arrow. Scale bar, 2 micrometers. FIG. 3C shows measured photocurrent as a function of incident power at reverse bias voltages of 0 V, 1 V, 2 V, and 3 V (going from bottom to top). FIG. 3D shows measured device responsivity as a function of incident power at reverse bias voltages of 0 V, 1 V, 2 V, and 3 V (going from bottom to top).

FIGS. 3E-3G show spatially-resolved photocurrent measurements. FIG. 3E is a schematic showing the multiple line-scans in the x-direction carried out at different crossing points of the nanowire (s1-s11): (s1) line-scan through the nanowire tip; (s2-s9): line-scans through the core/shell section with 300 nm increments from the tip along the nanowire axis (y-direction); (s10) line-scan through the core/shell section between the core/shell contacts (4.2 micrometers in the y-direction from the tip); (s11) line-scan through the core-only section between the core/shell contacts (6.6 micrometers in the y-direction from the tip). FIG. 3F shows measured scanning photocurrents near nanowire tip (s1-s9). The nanowire tip is defined as the origin of the x and y coordinates. FIG. 3G shows measured scanning photocurrents through the tip (s1), the core/shell (s10) and core-only (s11) sections between the core/shell contacts. The incident power was ˜29.3 microwatts for all the line-scans.

### EXAMPLE 4

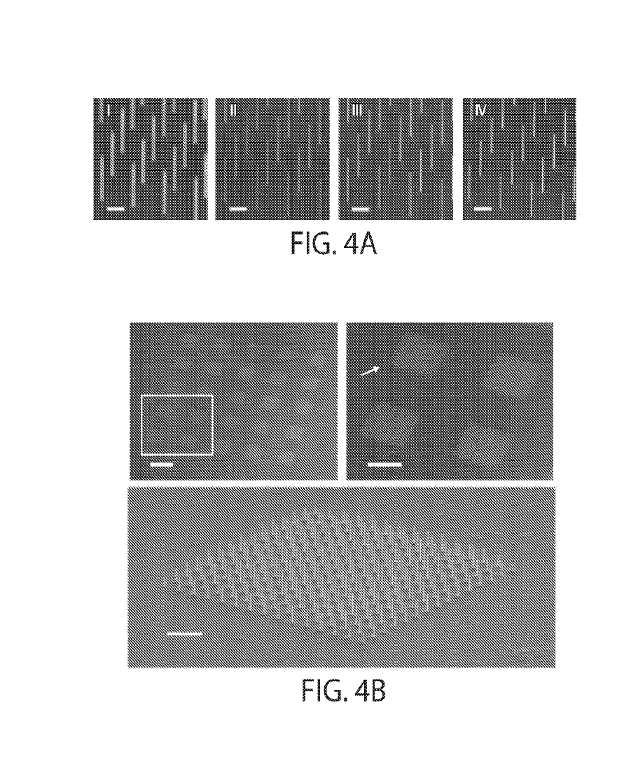

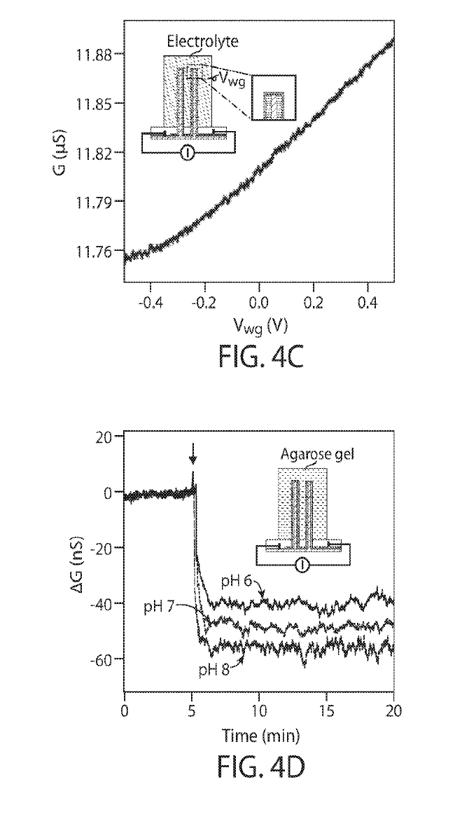

This example shows a top-down approach to synthesize vertical arrays of tip-modulated nanowires for potential wafer-size synthesis and fabrication (FIG. 4A). The tip-modulated nanowire array synthesis started with definition of arrayed masks, which were patterned by electron-beam lithography on highly doped p-Si wafer. For this step, photolithography can be used alternatively for further scale-up. Next, vertical nanowire arrays were formed via deep reactive ion etching (FIG. 4A; I) and were subsequently wet-etched in KOH aqueous solution to reduce the diameter (FIG. 4A; II). After conformal deposition of SiO₂ on the nanowire array via ALD (FIG. 4A; III), tips of the nanowire arrays were removed, similar to the bottom-up synthesis (FIG. 9). Finally, the highly doped n-Si shell was deposited in CVD to yield the tip-modulated nanowire arrays (FIG. 4A; IV). It was noted that a synthetic yield close to 80% was achieved with only nanowires longer than 10 micrometers being counted (FIG. 4B). Additionally, the as-synthesized nanowire arrays could be harvested by shear-transfer, contact-printing and nanocombing to a planar substrate. They could also be fabricated into vertical tip-modulated nanowire device array with a few more simple fabrication steps (see below).

The tip-modulated nanowire device array was fabricated by defining contacts to the p-Si substrate and the n-Si shell. To measure the collective transconductance of the nanowire device array, the water-gate experiment was performed by using the electrolyte as the top-gate, similar to the single device measurement (FIG. 4C). The collective transconductance of 132.3 nS/V shows the arrayed device could also function as a potentiometer. In addition, to further exploit the unique three-dimensional device geometry, sensing measurements were carried out with agarose gels of different pHs serving as the top-gate (FIG. 4D). When the gels were gently placed on top of the tip-modulated nanowire device array, the device conductance showed clear baseline changes, of which the value depends on the pH of the gel. The device sensitivity, calibrated by the device transconductance, was measured ˜58 mV/pH. This result suggests that the nanowire device array can protrude into soft materials and serve as a highly sensitive potentiometer and chemical sensor.

FIG. 4 shows top-down synthesis and fabrication of vertical tip-modulated nanowires and nanowire device array. FIG. 4A shows top-down synthesis of tip-modulated nanowire arrays: (I) deep reactive ion etching (DRIE) of p-Si <111> wafer; (II) KOH wet etching to thin down p-Si nanowire arrays; (III) conformal ALD deposition of SiO₂ insulation layer; (IV) removal of the tip and conformal VS n-Si shell growth in CVD. Scale bars, 5 micrometers. FIG. 4B shows SEM images of as-synthesized tip-modulated nanowire arrays. Top left: low magnification SEM image (45 degree tilt) of 25 tiles of 15×15 tip-modulated nanowire arrays. Scale bar, 200 micrometers. Top right, high magnification SEM image of the nanowire tiles in the box. Scale bar, 100 micrometers. Bottom, high-angle SEM image (70 degree tilt) of a 15×15 nanowire tile (view angle specified by the arrow). Scale bar, 20 micrometers. FIG. 4C shows measured water-gate response of 70 vertical tip-modulated nanowires (0.7 V forward bias). Inset, schematic showing the vertical tip-modulated nanowire device array structure and the water-gate measurement setup. The p-type Si wafer, SiO₂ layer, n-Si shell, passivation layer are arranged innermost to outermost in the insert in FIG. 4C. FIG. 4D shows measured conductance changes of 70 vertical tip-modulated nanowires (0.7 V forward bias) when agarose gels of pH 6, 7, and 8 (proceeding from top to bottom in this figure) were placed on the nanowire array. The gel placement is specified by the arrow. Inset, schematic showing the gel pH sensing measurement setup with the gel on the nanowire array.

FIG. 9 show top-down synthesis of tip-modulated nanowire arrays. SEM images (45 degree tilt) of nanowire tip removal before (left) and after (right) the ultrasonication in synthetic step (IV) in FIG. 4A. Scale bars, 5 micrometers.

In summary, these examples demonstrate the design principle, synthetic strategy and device fabrications of a novel nanowire structural motif, termed tip-modulated nanowires. The new nanowire structure can be further generalized to combinations of different materials for the core, the shell and the insulation layer. For example, similar to the tip Si p-n junction, a Si p-i-p junction can be formed at the tip to function as a nanoFET device. Semiconductor heterojunctions, such as Si/III-V and Si/II-VI junctions can be encoded at the nanowire tip as localized LED devices. In addition, Ge/Si and GaAs/AlGaAs junctions can be encoded to form, for example, an Esaki diode or a quantum dot for quantum electronics and photonics applications. The vertical tip-modulated nanowire device array also provides a platform for chemical and biological sensing in vitro or in vivo, allowing large-scale and multiplexed detection of electrical and chemical potentials at the nanowire array tips.

### EXAMPLE 5

Following are various materials and methods used in the above examples.

Si p-n junction tip-modulated nanowire synthesis. Si nanowire cores were grown by gold-nanoparticle catalyzed vapor-liquid-solid (VLS) process on Si <111> substrates (p-type, 3-5 Ohm cm, Nova Electronic Materials). Briefly, 50 nm diameter gold nanoparticles (Ted Pella) were suspended in 10% aqueous HF solution and dispersed on Si <111> substrates, which was pretreated with buffered oxide etch (BOE 7:1, J.T. Baker). The epitaxial p-type Si nanowire core growth was carried out using SiH₄ (1-2 sccm), B₂H₆ (14 sccm), and H₂ (4-5 sccm) at a total pressure and temperature of 10 torr and 500° C., respectively. The SiO₂ insulation layer (˜50 nm) was conformally deposited with atomic layer deposition (ALD, Savannah-S200, Cambridge NanoTech) at 250° C. Subsequently, the nanowire tip was removed by ultrasonication: the growth substrate was first coated with a protective resist layer (SU-8 2005 or 2010, MicroChem Corp., prebaked at 95° C. for 3 min), which was etched down using oxygen plasma stripper (PJ-II, AST Products Inc., 50 W for 1-2 h) to expose the nanowire tips. The nanowire tips were then removed by ultrasonication (500D, Crest Ultrasonics) at 120 W for 1 min. Finally, the SU-8 protection layer was removed by rinsing in acetone and the substrate was further cleaned with oxygen plasma stripper (150 W for 30 min). Following the tip removal, the growth substrate was treated with BOE (Buffered Oxide Etch) for 4 s and immediately transferred to the CVD chamber. The n-Si shell growth was carried out by uncatalyzed vapor-solid (VS) process using SiH₄ (0.15 sccm), PH₃ (0.15-0.75 sccm), and H₂ (60 sccm) at a total pressure and temperature of 25 torr and 775° C., respectively.

Tip-modulated nanowire device fabrication. As-synthesized Si p-n junction tip-modulated nanowires were shear transferred to silicon nitride substrates (100 nm thermal SiO₂, 200 nm SiNₓ, n-type, 0.005 V cm, Nova Electronic Materials). SU-8 (2000.5, MicroChem Corp.) etch mask was defined with electron-beam lithography (EBL) to protect the shell on the tip end of the nanowire. After 6 s etch with BOE to remove the native oxide, the nanowires were etched for 40 to 60 s with KOH (20 vol % in water, 60° C.) to remove the n-Si shell. The SU-8 etch mask was subsequently removed by UV-ozone stripper (300° C., 40 min). MMA/PMMA resist (MicroChem Corp.) was spin-coated and patterned by EBL for the core and shell contacts. The nanowires were etched for 50 s with BOE to remove the SiO₂ layer for the core contact before thermal evaporation (Ti/Pd, 3/450 nm) to metalize the contacts.

Electrical characterization. I-V characteristics of the tip-modulated nanowire devices were measured with a probe station (TTP-4, Desert Cryogenics) and a DAC card (PCI-6030E, National Instruments, Inc.) under computer controls and with a semiconductor parameter analyzer (4156 C, Agilent Technologies). Water-gate experiments were carried out with devices submerged in 1× PBS solution with a Ag/AgCl reference electrode inserted to apply gate voltage (V_{wg}). The source-drain current of the device was amplified by a current preamplifier (1211, DL Instruments) at sensitivity of 10⁻⁶ or 10⁻⁷ A/V, filtered (60 kHz, CyberAmp 380, Molecular Devices, Inc.), and digitized at 250 kHz sampling rate (Axon Digidata 1440A Data Acquisition System, Molecular Devices, Inc.).

Optical characterization. For the scanning photocurrent experiments, a Si p-n junction tip-modulated nanowire device was mounted on a piezo-controlled movable stage (Digital PI PZT flexure stage) to spatially control the nanowire tip position. The device was optically pumped at room temperature by a 488 nm Ar-ion CW laser, which was focused to a spot of ˜1.6 micrometers in diameter using a x40 microscope objective lens with a numerical aperture (N.A.) of 0.65. The photocurrent was measured under laser illumination or in the dark using a semiconductor parameter analyzer (4156 C, Agilent Technologies) as the laser spot was aligned to or spatially scanned through the nanowire tip. The device responsivity was obtained from dividing the measured photocurrent by the incident power. The incident power was measured by considering the area fraction of the nanowire within the laser spot as the tip was aligned at the center of the spot.

Top-down synthesis and fabrication of tip-modulated nanowires and the nanowire device array. SU-8 (2002) resist masks were defined on Si <111> substrate (p-type, 0.001-0.005 Ohm cm, Nova Electronic Materials) by EBL and hard-baked at 180° C. for 20 min. After deep reactive ion etching (DRIE, SPTS Technologies), the substrate was cleaned with oxygen plasma stripper at 150 W for 30 min and the nanowires were thinned down to ˜300 nm in diameter with KOH (20 vol % in water, 60° C.). Subsequent conformal ALD growth of the SiO₂ insulation layer, ultrasonication removal of the nanowire tips, and the conformal n-Si shell growth, similar to the procedures described in the bottom-up synthesis, yielded tip-modulated nanowire arrays.

To fabricate the chip into the tip-modulated nanowire device array, part of the n-shell was removed by 20 s etch in KOH (20 vol % in water, 60° C.). The tip-modulated nanowire arrays were protected by SU-8 (two layers of 2010) resist masks during the etching. The core and shell contact pads were then patterned by EBL. The chip was etched for 50 s with BOE to remove the SiO₂ layer for the core contact before thermal evaporation (Ti/Pd, 3/120 nm) to metalize the contact pads. Water-gate measurements were carried out with a probe station (TTP-4, Desert Cryogenics) and a DAC card (PCI-6030E, National Instruments, Inc.), at a typical ramp rate of 2 mV/s. The gel pH measurements were carried out using 1% agarose gel prepared from phosphate buffers of pH 6, 7 and 8. The device conductance changes were measured with the same set-ups using 2 Hz sampling rate.

### EXAMPLE 6

In this example, certain nanowires were prepared using a wafer-scale top-down synthesis approach using deep reactive-ion etching (DRIE). A silicon substrate was prepared, certain portions masked, then the substrate etched, e.g., using SF₆ or C₄F₈. The etching may be directional and the directional ions attack the passivation layer at the bottom and sputter or chemically etch the Si from the substrate.

The mask was an SU-8 resist mask (MicroChem SU8 2002; EBL), and was defined on a p-type Si wafer (P/B0 <111> off 4° 0.001-0.005 Ohm cm, 356-406 micrometers). The wafer was etched down vertically via DRIE for 15-20 micrometers in depth. The remaining organics (deposited on the side wall for passivation in the Bosch process) were removed by oxy-plasma (150 W/20 min) after DRIE etch. SEM images showed p-type Si nanowires after 10 min in oxy/plasma. The SU-8 mask still remains on top of the nanowires on the substrate.

Next the nanowires were thinned using KOH wet etching. The p-type nanowire cores were thinned down to 200-300 nm diameter with up to 4 min KOH etching (20 wt %; 60° C.). Afterwards, 40-50 nm SiO₂ was deposited with ALD (250° C.).

For the nanowire tip removal, an SU-8 protective resist layer (2010 or 2005, Microchem) was spin-coated onto the nanowires. The protective resist layer was then etched down to expose the nanowire tip of desirable lengths (oxy-plasma, conditions depend on the targeted etching length). The nanowire tip was then removed by ultrasonication (125 W, 3 min). The protective resist layer was then removed by acetone and oxy-plasma etching/cleaning.

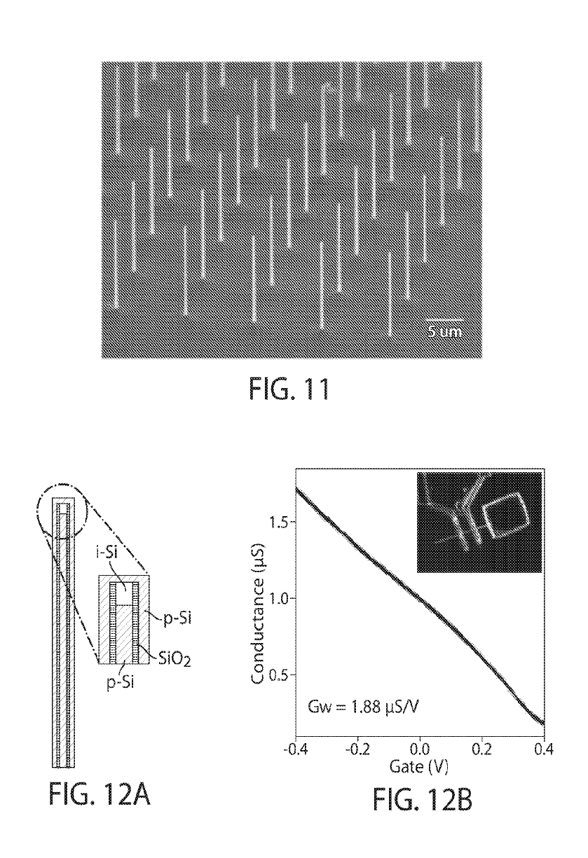

Afterwards, n-type Si shell growth was performed as follows. The substrate was etched in BOE for 4 s and immediately transferred to a CVD furnace. An n-type Si shell (˜40 nm) was then deposited at 775° C. with a 500:1 feeding ratio of SiH₄/PH₃. Examples of these may be seen in FIG. 11.

### EXAMPLE 7

This example illustrates a p-Si/i-Si/p-Si tip junction prepared according to another embodiment of the invention. See FIG. 12A.

In this example, doping of the p-core of the nanowire was modulated from highly doped p-type silicon to intrinsic silicon during epitaxial growth (intrinsic region 8-10 micrometers long from the tip), followed by controlled removal of the tip (about ˜5 micrometers being removed).

In detail, highly doped Si nanowire cores were epitaxially grown by 50 nm gold-nanoparticle catalyzed vapor-liquid-solid (VLS) process using SiH₄ (1-2 sccm), B₂H₆ (14 sccm), and H₂ (4-5 sccm) at total pressure and temperature of 10 torr and 500° C. on Si <111> substrates (p-type, 3-5 Ohm cm, Nova Electronic Materials) and the B₂H₆ precursor gas was turned off for the last 10-15 min for the growth of the intrinsic region (˜8-10 μm long). An SiO₂ insulation layer (˜50 nm) was conformally deposited with atomic layer deposition (ALD, Savannah-S200, Cambridge NanoTech) at 250° C. and the nanowire tip was subsequently removed by ultrasonication as described. Note that the protective resist layer was etched down to expose ˜5 micrometer tips with oxygen-plasma etching before the ultrasonication removal of the tips. The substrate was briefly treated with BHF for about 30 s to etch back the SiO₂ insulation for 500 nm-1 micrometer before the removal of the protective resist layer. The p-Si shell growth was carried out by uncatalyzed vapor-solid (VS) process using SiH₄ (0.15 sccm), B₂H₆ (1.5 sccm), and H₂ (60 sccm) at a total pressure and temperature of 25 torr and 775° C., respectively.

The core and shell contacts were defined as described in fabrication of the tip-modulated nanowire device with the p-n junction. Water-gate measurements show a p-type FET response, as can be seen in FIG. 12B, showing the tip-modulated nanowire device with the p-Si/i-Si/p-Si junction functions as a localized FET device.

### EXAMPLE 8

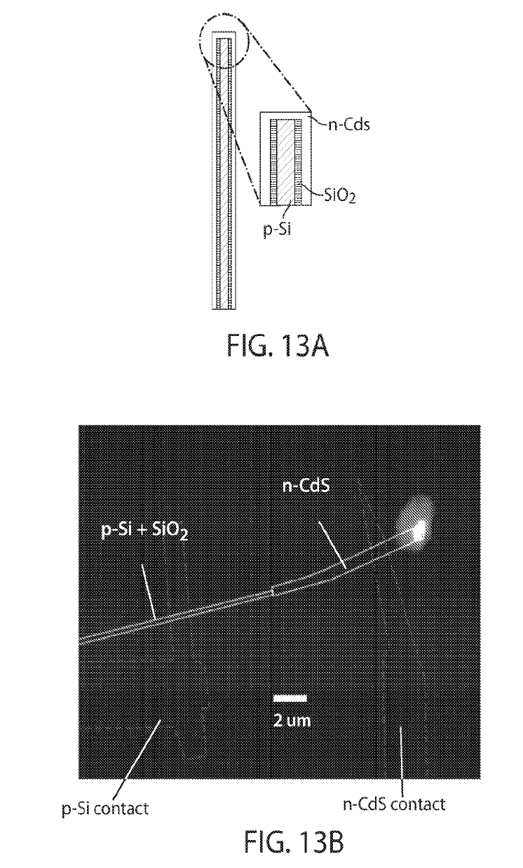

This example shows a p-Si/CdS tip heterojunction made in accordance with another embodiment of the invention. See FIG. 13A. In this example, a CdS shell was deposited conformally to a p-Si/SiO₂ (tip removed) nanowire in a three-zone furnace.

In detail, highly doped Si nanowire cores were epitaxially grown by 50 nm gold-nanoparticle catalyzed vapor-liquid-solid (VLS) process using SiH₄ (1-2 sccm), B₂H₆ (14 sccm), and H₂ (4-5 sccm) at total pressure and temperature of 10 torr and 500° C. on Si <111> substrates (p-type, 3-5 Ohm cm, Nova Electronic Materials), as previously described in the synthesis of tip-modulated nanowires with a tip Si p-n junction. The SiO₂ insulation layer (˜50 nm) was conformally deposited with atomic layer deposition (ALD, Savannah-S200, Cambridge NanoTech) at 250° C. and the nanowire tip was subsequently removed by ultrasonication as described. Before the protective resist layer removal, the substrate was briefly treated with BHF for about 30 s to etch back the SiO₂ insulation for 500 nm-1 micrometers. The CdS shell growth was carried out with physical vapor deposition (PECVD) in a three-zone furnace immediately after brief treatment in BHF (10 s) to remove the nanowire tip oxide. CdS was evaporated at 710° C. from zone one and deposited on the substrate in zone two at 550° C. for 20 minutes. As-synthesized p-Si/CdS heterojunction tip-modulated nanowires were shear transferred to silicon nitride substrates (100 nm thermal SiO₂, 200 nm SiNₓ, n-type, 0.005 V cm, Nova Electronic Materials). The MMA/PMMA etch mask was defined with e-beam lithography (EBL) to only expose part of the CdS shell to be removed. After 6 s in HCl aqueous solution for the CdS shell etch, the MMA/PMMA mask was removed by acetone. The core and shell contacts were patterned with MMA/PMMA and metalized by thermal evaporation (3/550 nm Ti/Pd) after 50 s in BHF to remove the SiO₂ layer for the core contact.

IV characteristics of the p-Si/CdS heterojunction tip-modulated nanowire was measured with a probe station (TTP-4, Desert Cryogenics) and a DAC card (PCI-6030E, National Instruments, Inc.) under computer controls. In electroluminescence (EL) experiment, a current pulse of about 7 microamperes with a width of 4.6 s and a period of 7 s was injected into the tip Si/CdS heterojunction nanowire device. The light emitted from the junction area was collected by the same objective lens and was focused onto a liquid nitrogen cooled CCD camera (LN/CCD-1340/700-EB/1, Princeton Instruments). Localized electroluminescence (EL) was observed near the tip of the nanowire, thus showing that the p-Si/CdS heterojunction within the nanowire was able to function as a LED. See FIG. 13B.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

When the word “about” is used herein in reference to a number, it should be understood that still another embodiment of the invention includes that number not modified by the presence of the word “about.”

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. An article, comprising:
a nanowire comprising a core, an inner shell surrounding the core except at an end of the core, and an outer shell surrounding the inner shell and contacting the end of the core.

2. The article of claim 1, wherein the nanowire is substantially cylindrical.

3. The article of claim 1, wherein the inner shell is an insulator.

4-10. (canceled)

11. The article of claim 1, wherein the nanowire comprises a semiconductor.

12-14. (canceled)

15. The article of claim 1, wherein the nanoscale wire has an overall diameter of less than about 1 micrometer.

16. The article of claim 1, wherein the core has a diameter of less than about 1 micrometer.

17. (canceled)

18. The article of claim 1, wherein the outer shell has a shell thickness of less than about 100 nm.

19. (canceled)

20. The article of claim 1, wherein the inner shell has a thickness that is less than about 10% of the average diameter of the nanowire.

21-26. (canceled)

27. The article of claim 1, wherein the nanowire is part of an optoelectrical device.

28. The article of claim 1, wherein the nanowire comprises more than one outer shell.

29. (canceled)

30. An article, comprising:
a nanowire comprising a core having an end portion, an inner shell surrounding the core except at the end portion, and an outer shell surrounding the inner shell and contacting the core at the end portion.

31-87. (canceled)

88. A method, comprising:
providing a nanowire vertically oriented on a substrate;
coating the nanowire with a first material;
selectively removing a portion of the first material from an end of the nanowire; and
coating the nanowire with a second material.

89-90. (canceled)

91. The method of claim 88, comprising depositing a particle on the substrate, and growing the nanowire from the particle.

92-93. (canceled)

94. The method of claim 91, wherein the nanowire is grown from the particle via epitaxial vapor-liquid-solid growth.

95. The method of claim 91, wherein providing the nanowire vertically oriented on the substrate comprises selectively etching the substrate to form the vertically oriented nanowires.

96-104. (canceled)

105. The method of claim 88, wherein selectively removing the portion of the first material from the end of the nanowire comprises at least partially embedding the nanowire in resist.

106. (canceled)

107. The method of claim 105, further comprising removing a portion of the resist to expose the end of the nanowire.

108. The method of claim 105, further comprising removing an end portion of the nanowire while the nanowire is embedded within the resist.

109-110. (canceled)

111. The method of claim 108, further comprising removing the resist after removing the end portion.

112-118. (canceled)

119. The method of claim 88, further comprising removing the nanowire from the substrate.

120. (canceled)
